(19) United States
(12) Patent Application Publication
(10) Pub. No.: US 2026/0059687 A1
(43) Pub. Date: Feb. 26, 2026

(54) SERVER SUPPORT SYSTEMS AND METHODS

(71) Applicant: CIS Global LLC, Tucson, AZ (US)

(72) Inventors: Karl Klaus Dittus, Raleigh, NC (US); Yan Li, Jiangsu (CN); Jiafeng Wang, Jiangsu (CN); Jichao Wang, Jiangsu (CN)

(21) Appl. No.: 18/811,078

(22) Filed: Aug. 21, 2024

(51) Int. Cl. H05K 7/14; H05K 7/20

(52) U.S. Cl. CPC H05K 7/1489; H05K 7/20236; H05K 7/20772

(57) ABSTRACT

A server system for use with a tank that contains cooling fluid can include a server slide that is immersible within the cooling fluid to movably support a server chassis relative to the tank and the cooling fluid. The server slide can be extendable along a vertical direction between a contracted orientation and an extended orientation. The server system can further include a support leg secured to the server chassis in a first position, the support leg being moveable from the first position to a second position in which the support leg supports the server chassis at an angle relative to a horizontal plane.

### CROSS-REFERENCE TO RELATED APPLICATIONS

Not Applicable.

### BACKGROUND

Servers may include hardware and software that provide resources, data, services, or programs to other computing devices. Due to the increase in data consumption and computational demands, some server components (e.g., various electronic components supported by a server chassis) may be at risk of overheating during use.

### SUMMARY

Some embodiments of the invention provide a server system for use with a tank that contains cooling fluid. The server system can include a server slide that is immersible within the cooling fluid to movably support a server chassis relative to the tank and the cooling fluid. The server slide being extendable along a vertical direction between a contracted orientation, in which the server slide supports the server chassis with the server chassis submerged within the cooling fluid, and an extended orientation, in which the server slide supports the server chassis with the server chassis at least partly outside the cooling fluid. The server system can further include a support leg secured to the server chassis in a first position, the support leg being moveable from the first position to a second position in which the support leg supports the server chassis at an angle relative to a horizontal plane.

Some embodiments of the invention provide a method of supporting a server system for use with a tank that contains cooling fluid. The method can include moving a server chassis upward along a vertical direction to raise the server chassis out of the tank of cooling fluid, pivoting a first support leg, relative to the server chassis, to extend at a first-leg non-zero angle relative to an elongate direction of the server chassis, and supporting the server chassis with the first support leg, to drain the cooling fluid from the server chassis, with the server chassis at a chassis non-zero angle relative to a horizontal plane.

Some embodiments of the invention provide a server system. The server system can include a tank that contains cooling fluid, a server chassis, a server slide secured to the server chassis to slidably move the server chassis along a vertical direction between a contracted orientation, in which the server slide supports the server chassis with the server chassis submerged within the cooling fluid, and an extended orientation, in which the server slide supports the server chassis with the server chassis at least partly outside the cooling fluid, and a first support leg that is pivotable relative to the server chassis to extend at a first-leg non-zero angle relative to an elongate direction of the server chassis to support the server chassis at a chassis non-zero angle relative to a horizontal plane, to drain the cooling fluid from the server chassis.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIGS. 1A and 1B are diagrammatic views of an immersion cooling system according to aspects of the present disclosure.

FIG. 2 is an axonometric view of an example implementation of the immersion cooling system of FIGS. 1A and 1B.

FIG. 3 is a side elevation view of a support system for a server of the immersion cooling system of FIG. 2.

FIG. 4 is an enlarged side elevation view of the portion of the support system labeled IV in FIG. 3.

FIG. 5 is an enlarged side elevation view of the portion of the support system labeled V in FIG. 3.

FIG. 6 is an axonometric partial cross-sectional view of a release mechanism of the support system of FIG. 5, taken along plane VI-VI of FIG. 3.

FIG. 7 is an enlarged top plan cross-sectional view of the release mechanism of FIG. 6.

FIG. 8 an enlarged side elevation view of the portion of the support system labeled VIII in FIG. 3.

FIG. 9 is a side elevation view of a server of the immersion cooling system of FIG. 2 in an expanded position.

FIG. 10 is a side elevation view of the server of FIG. 9 in a first stage of a maintenance position transition process.

FIG. 11 is a side elevation view of the server of FIG. 9 in a second stage of the maintenance position transition process.

FIG. 12 is a side elevation view of the server of FIG. 9 in the maintenance position, supported by the support system of FIG. 3.

FIG. 13 is a side view of the server of FIG. 9 in the maintenance position, supported by another example of a support system.

### DETAILED DESCRIPTION

The following discussion is presented to enable a person skilled in the art to make and use embodiments of the invention. Given the benefit of this disclosure, various modifications to the illustrated embodiments will be readily apparent to those skilled in the art, and the principles herein can be applied to other embodiments and applications without departing from embodiments of the invention. Thus, embodiments of the invention are not intended to be limited to embodiments shown, but are to be accorded the widest scope consistent with the principles and features disclosed herein.

The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

As generally noted above, it may be important to cool servers and related assemblies to prevent overheating, which may cause damage to the servers. In some cases, air cooling of servers may not be adequate to cool the servers to the desired temperature. In this regard, compared with air-cooled servers, liquid-cooled servers may be more effective in cooling the servers. In some examples, it may be useful to install liquid-cooled servers vertically (e.g., for vertical movement in and out of a coolant bath). However, this arrangement can make servicing or performing other maintenance on the servers difficult. For example, an interior of servers may be filled with a cooling fluid, which may need to be drained prior to performing maintenance on the server. This need may add to the overall complexity and inefficiency of maintenance operations.

In one example, an immersion cooling system may include a tank defining an interior volume configured to retain cooling fluid (e.g., a dielectric liquid) to facilitate efficient cooling of one or more servers. In one example, the servers may be slidably secured within the tank via one or more server slides. The server slides may be secured in a vertical arrangement (e.g., mounted to one of more sides of the tank via one or more brackets of generally known configurations).

In one example, a user may extend or contract vertically installed server slides to insert or remove the server from within the cooling fluid of the tank. For example, a user may extend a server slide (e.g., may telescopically extend the server slide) to remove the server from the tank and the cooling fluid. Similarly, a user may retract (e.g., compress) the server slide to return the server to the tank and the cooling fluid for operation. As noted above, however, in some cases, the servers may require maintenance and thus may need to be positioned in a way that facilitates the draining of cooling fluid from the server (e.g., while also facilitating the performance of maintenance on the server).

To assist in the draining of cooling fluid from the server, without the need to transport the server to a remote location for maintenance (e.g., disconnect the server from the server slide(s)), the server may include a support system according to examples of the disclosed technology. The support system may be used to temporarily support the server (e.g., a server chassis) at an angle relative to a horizontal plane (e.g., a plane defined by an upper surface of the side walls of the tank). For example, the support system may be used to support the server chassis at an angle of 5 degrees to 60 degrees, inclusive, with respect to the horizontal plane (e.g., while also holding the server chassis at least partly out of the cooling fluid). Thus, cooling fluid located within the server may drain from the server (e.g., back into the tank). Further, the server may thus also be positioned so that an operator may perform maintenance on the server chassis (or internal components thereof) locally (e.g., at the tank), without having to disconnect the server from the server slide(s) and transport the server to another location.

In one example, the support system may include a first support leg that is pivotable relative to a sever chassis to support the server chassis at a non-zero angle relative to a horizontal plane (e.g., plane defined by the top of the tank) to permit draining of cooling fluid from the server chassis. The first support leg may be pivotable relative to an elongate direction of the server chassis to support the server chassis at the above-referenced angle. Further, the first support leg may form at least part of a rail of the server slide (e.g., the rail that guides slidable movement of the server slide).

In addition to the first support leg, the support system may include a second support leg that is pivotably secured to the server chassis, so that the server chassis may pivot relative to the (fixed) second support leg. Put differently, the second support leg may further support the server chassis at the chassis non-zero angle, but may not pivot relative to the chassis itself. Further, the second support leg and the first support leg may collectively form the rail of the server slide when the first support leg is aligned with the elongate direction of the server chassis.

In one example, to perform maintenance on the server chassis, a user may first move the server chassis upward along a vertical direction (e.g., vertically via the rails, in parallel with an elongate direction of the server chassis) to raise the server chassis out of the tank of cooling fluid. Following this, the user may pivot the first support leg relative to the server chassis (e.g., away from the elongate direction) to extend the first support leg at a non-zero angle relative to the elongate direction of the server chassis. Once the first support leg is extended, the user may support the server chassis via the first support leg to drain the cooling fluid from within the server chassis. For example, the first support leg can be removably engaged with a tank wall or other rigid support. As mentioned previously, in some examples, the first support leg may support the server chassis at a non-zero angle relative to a horizontal plane (e.g., defined by the top of the tank) and cooling fluid can then drain from the chassis to allow further maintenance operations. In another example, the first support leg may support the server chassis at an angle of 0-60 degrees relative to the horizontal plane.

Further, to arrange the server chassis at the non-zero (or including zero) angle relative to the horizontal plane, the user may pivot the server chassis relative to a pivot point defined by a second support leg, so that the elongate direction of the server chassis extends at non-zero angle relative to the second support leg. Additionally, the second support leg may provide support to the server chassis to hold the server chassis at the non-zero angle relative to the horizontal plane (e.g., in combination with the first support leg).

In various example, the support system may include one or more support legs (e.g., one, two, three, four, etc.) pivotally secured to the server chassis. The support legs may include a first release mechanism, which may be actuated by an operator to permit relative movement of the support leg with respect to the server chassis (e.g., slidable movement). In some cases, spring-biased locking mechanisms of various designs can be used to selectively lock support legs relative to a server chassis (e.g., in alignment to serve as a rail of an extendible rail system) and to unlock the support legs for movement to a pivoted orientation. In some cases, a support leg can be slidable along a server chassis to unlock the support leg for movement to a pivoted orientation.

In some examples, a locking system can selectively release a support leg to be slid relative to a chassis (or vice versa) to thereby permit pivoting movement at the support leg. For example, actuation of a first release mechanism from a locked position into an unlocked position may engage a cantilevered retention spring, which may disengage a stopper from within an opening of the server chassis and permit movement (e.g., sliding) of the support leg with respect to the server chassis. Correspondingly, once the support leg is sufficiently moved with respect to the server chassis, a tab may be removed from within a cutout at an end of the support leg, which may unlock rotational (e.g., pivotal) movement of the support leg with respect to the server chassis.

In another example, the support system may further include a support leg configured as a server slide pivotally secured to the server chassis. The server slide may include a second (or other) release mechanism, which may be actuated by an operator to permit relative movement of the server chassis with respect to the server slide (e.g., slidable movement). For example, actuation of the second release mechanism into an unlocked position may engage a cantilevered retention spring, which may disengage a stopper from within an opening of the server chassis and permit movement of the server chassis with respect to the server slide. Correspondingly, once the server chassis is actuated with respect to the server slide, a tab may be removed from within a cutout positioned an end of the server slide, which may unlock rotational (e.g., pivotal) movement of the server chassis with respect to the server slide.

In some examples, support legs can be provided on opposing sides of a server chassis, to collectively support the server chassis at a particular angle. Thus, arrangements and operations as mentioned above, may in some cases be included or performed for two opposing sides of a server chassis. For example, one or more support legs on each of two sides of a server chassis can be collectively or individually slid along the server chassis to allow relative pivotal movement between the server chassis and the support leg(s), and support of the server chassis by the support leg(s) at a predetermined angle (e.g., 0 to 60 degrees, inclusive, with respect to a horizontal plane defined by an upper surface of the walls of the tank), and the server chassis may be supported by the support leg so that the server chassis may drain of cooling fluid, while also being in a position for maintenance.

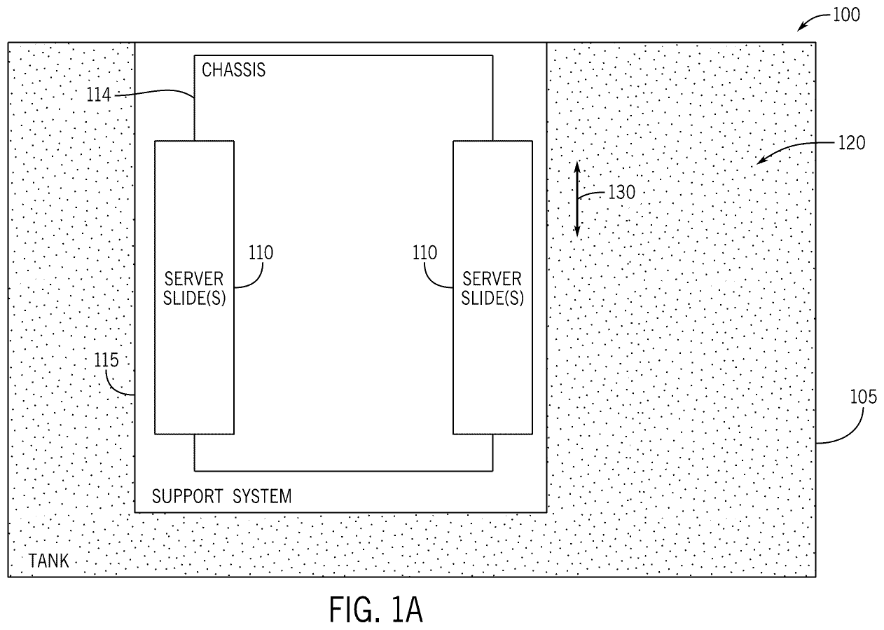

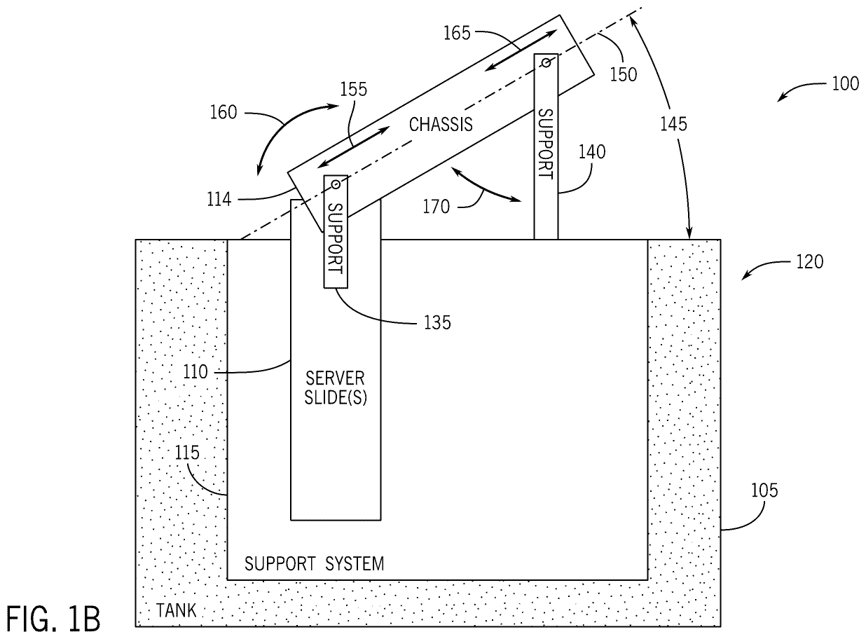

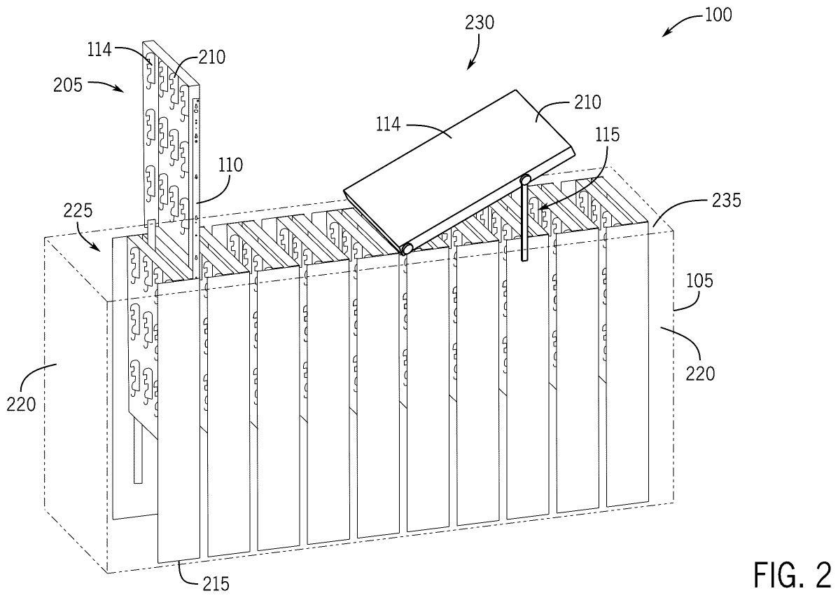

FIGS. 1A and 1B show an example of an immersion cooling system 100 including a tank 105, which may be filled with a cooling fluid 120. In one example, the cooling fluid 120 may be a dielectric liquid (e.g., mineral oil, purified water, benzene, liquid nitrogen, etc.). Generally, the tank 105 may include one or more walls 220 configured to form a liquid-tight volume with a top opening 225 to retain the cooling fluid 120. In one particular example, an upper surface 235 of the walls 220 may form a substantially horizontal plane (see, e.g., FIG. 2).

To facilitate efficient cooling of a server 210 (i.e., a component of a server chassis 114), the server 210 may be immersed within the cooling fluid 120 (e.g., fully immersed). Further, the server 210 may be held in a slidable relationship with the tank 105 via one or more server slides 110 (e.g., as secured to the walls 220 of the tank 105 via one or more brackets 215, see, e.g., FIG. 2). Correspondingly, the server slide(s) 110 can be extended or retracted to move the server 210 into and out of the cooling fluid 120.

In one example, the server slides 110 may be vertically oriented within the tank 105, so that a user may pull vertically to remove the server 210 from the tank (e.g., as shown by arrow 130). In one example, the server slides 110 may include a multi-rail telescoping assembly (e.g., as variously known in the art) that can support the server 210, which may include a server chassis 114 (e.g., as variously known in the art) housing various computational components. Thus, users may be able to change a position of the server 210 relative to the cooling fluid 120 via telescopic extension or retraction of the server slides 110. However, as mentioned previously, when the server 210 needs maintenance, the cooling fluid 120 must generally be drained from within the server chassis prior to the performance of maintenance on the server 210.

Thus, to facilitate the draining of cooling fluid 120 from within the server chassis 114, the server 210 may include a support system 115, which may include one or more first support legs 140 configured to support the chassis 114 to facilitate drainage of cooling fluid from within the chassis 114. The first support legs 140 may be pivotable from a first position, where the first support leg(s) 140 are aligned with an elongate axis 150 of the chassis 114, to a second position, where the first support leg(s) 140 are rotated (as shown by arrow 170) away from the elongate axis 150 by a non-zero amount to support the chassis 114 at an angle 145 (e.g., angle of 0 to 60 degrees, inclusive) relative to a horizontal plane. Put differently, the first support leg(s) 140 may pivot away from the chassis 114 to support the chassis at an angle 145, which facilitates the drainage of cooling fluid from within the chassis 114.

Additionally, the support system 115 may include one or more second support legs 135. The second support leg(s) 135 may permit pivotable movement of the chassis with respect to a vertical axis formed by the second support leg(s) 135 (e.g., as shown by arrow 160). Thus, the chassis 114 may pivot from a vertical position to an angled position (e.g., with respect to a horizontal plane) for drainage. Further, the second support leg(s) 135 may work with the first support leg(s) 140 to support the chassis 114 at the angle 145 relative to the horizontal plane.

In some examples, one or more of the first support legs 140 and one or more of the second support legs 135 together may form a part of one or more of the server slides 110 that permits supported movement (e.g., vertical movement) of the chassis 114. For example, when in the first position, aligned with the elongate axis of the chassis 114, the first support leg(s) 140 may form a part of the server slide(s) 110. In another example, when in the first position, the first support leg(s) 140 may align with the second support leg(s) 135 to form a part of the server slide(s) 110.

In some examples, to allow pivotal movement of the first support leg(s) 140 with respect to the chassis 114, the first support leg(s) 140 may be slidable with respect to the chassis 114 (e.g., as shown by arrow 165). Thus, prior to rotation of the first support leg(s) 140 as shown by arrow 170, the first support leg(s) 140 may first be slid relative to the chassis 114 as shown by arrow 165 to unlock rotational movement of the first support leg(s) 140. Correspondingly, to release pivotal movement of the chassis 114 with respect to the second support leg(s) 135, the chassis 114 may be slidable with respect to the second support leg(s) 135 (e.g., as shown by arrow 155). Thus, prior to rotation of the chassis 114 as shown by arrow 160, the chassis 114 may first be slid relative to the second support leg(s) 135 as shown by arrow 155 to unlock rotational movement of the chassis 114.

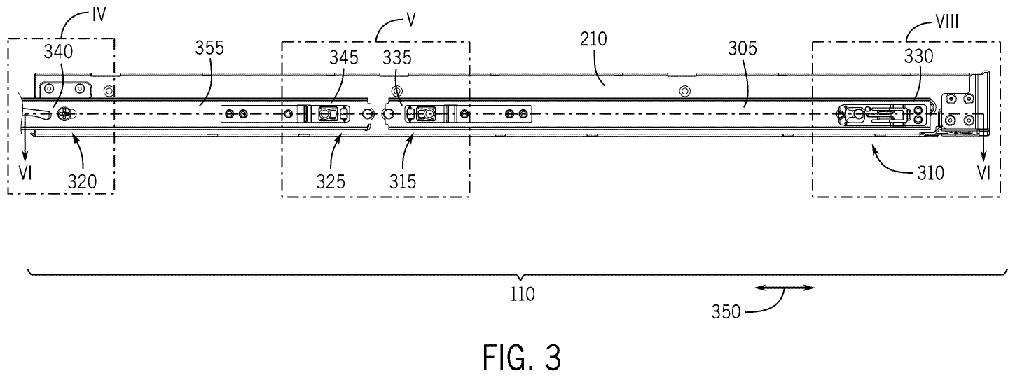

FIGS. 2 and 3 show one example implementation of the support system 115 for the chassis 114. The support system 115 may allow an operator to move the server 210 (e.g., via the chassis 114) out of the cooling fluid 120 (e.g., into an expanded position 205) and further into a maintenance position 230. In one example, in the maintenance position 230, the server 210 may be supported at an angle (e.g., between 5 and 60 degrees, inclusive) relative to the plane formed by the upper surface 235 of the walls 220 of the tank 105, so that cooling fluid 120 held within the server chassis 114 may drain from the server chassis back into the tank 105. Further, due to the angle of the server 210, an operator may perform maintenance on the server 210, without having to remove the server 210 from the server slides 110. In some examples, however, the server 210 can be held at a different angle for maintenance operations after draining (e.g., pivoted to horizontal, or held at a different angle by one or more support legs 305).

As mentioned previously, the support system 115 may include the one or more support legs 305 (e.g., a pair of support legs 305 on opposing sides of the server 210), which may be pivotally secured to the server 210 at a first end 330 of the support legs. In one example, the first end 330 of the support legs 305 defines a pivot point 310 for the support legs, which permits the support legs 305 to rotate with respect to the server 210 (e.g., to support the server 210 at an angle relative to the horizontal plane). In one particular example, the support legs 305 may rotate from a first position parallel to the server 210 to a second position angled away from the server 210. Opposite the pivot point 310, at a second end 335 of the support legs 305, the support legs may include a first release mechanism 315. The release mechanism 315 may permit an operator to release slidable movement of the support legs 305 with respect to the server 210. For example, actuation of the release mechanism 315 may permit an operator to slide the support legs 305 with respect to the server 210 as shown by arrow 350.

In one example, the support system 115 may further include a first rail 355 (e.g., an inner rail) of the server slide 110. In one example, the first rail 355 may be pivotally secured to the server 210 at a midpoint 340 of the first rail 355. In one example, the midpoint 340 of the first rail defines pivot point 320, which permits the server 210 to rotate relative to the vertical (e.g., fixed vertical) server slide 110 (e.g., including the fixed vertical first rail). The first rail 355 may further include a second release mechanism 325 positioned at a first end 345 of the first rail. Similar to the first release mechanism 315, the second release mechanism 325 may permit an operator to release slidable movement the server 210 with respect to the first rail 355. For example, actuation of the release mechanism 325 may permit an operator to slide server 210 with respect to the first rail 355 as shown by arrow 350.

In another example, both the first rail 355 and the support leg 305 together may form a portion of the server slide 110. For example, the first rail 355 and the support leg 305 may define the same surface profile and be aligned so that, when the server 210 is inserted into the tank 105, the support leg 305 may function as an extension of the first rail 355. Put differently, the support leg 305 may function as both a portion of the server slide 110 (e.g., for facilitating vertical insertion/removal of the server 210 from the tank 105) and also as a portion of the support system 115 (e.g., for supporting the server 210 at an angle relative to the horizontal plane for maintenance).

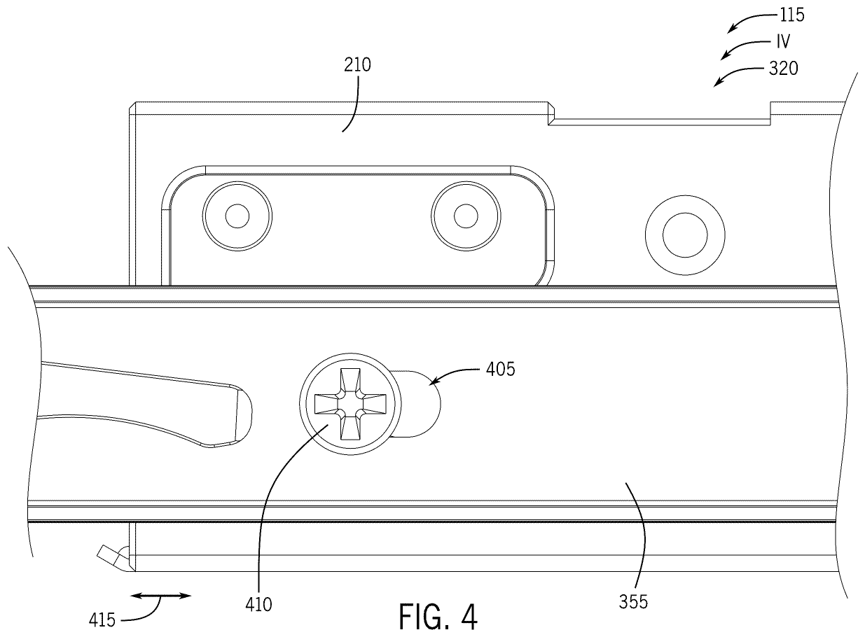

As mentioned previously, in order to facilitate pivotal movement between the first rail 355 and the server 210, the first rail 355 and the server 210 are connected via a pivot point 320. As shown in FIG. 4, the pivot point 320 is formed via a fastener 410 arranged through an elongate (e.g., oval) cutout 405 defined by the first rail 355. In one example, the cutout 405 is sized to permit lateral movement of the fastener 410 (and thus the server 210) within the cutout. Thus, as mentioned previously, the server 210 may have a predetermined amount of lateral movement (e.g., shown by arrow 415) with respect to the first rail 355.

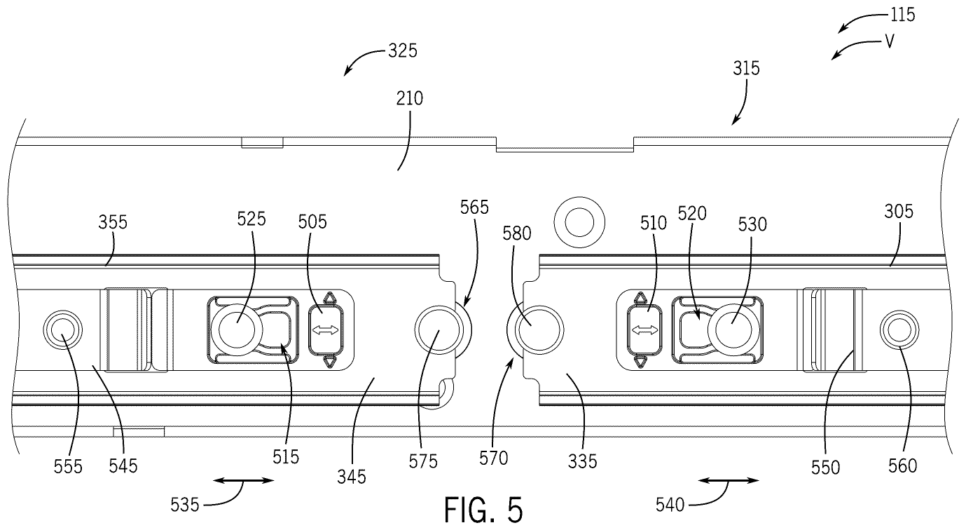

FIG. 5 shows an example of the release mechanisms 315, 325 of the support leg 305 and the first rail 355, respectively. In one example, the release mechanisms 315, 325 are similar in functionality and structure, with the difference being that the release mechanism 315 releases the support leg 305 with respect to the server 210, and the release mechanism 325 releases the server 210 with respect to the first rail 355.

In one example, the release mechanism 315 may include an actuator 510 defining a channel 520 that receives a protrusion 530 extending from the support leg 305. In one example, the actuator 510 may be moved between a first, locked position into a second, unlocked position (e.g., as shown by arrow 540) to release the support leg 305 with respect to the server 210. In one particular example, actuation of the actuator 510 from the locked position into the unlocked position causes an end of the actuator to engage a retention spring 550 (e.g., a cantilevered resilient member secured to the support leg at one end), which in turn separates a stopper 560 held within the spring 550 from the server 210 and permits movement of the support leg 305 with respect to the server 210. Correspondingly, with respect to the release mechanism 325, actuation of an actuator 505 of the release mechanism 325 from the locked position to the unlocked position (e.g., moving protrusion 525 within channel 515 as shown by arrow 535) engages a retention spring 545, which in turn disconnects a stopper 555 from the server 210 and permits movement of the server 210 with respect to the first rail 355.

In one example, once the release mechanisms 315, 325 have been actuated into the unlocked position, the server 210 may move (e.g., slide) relative to the first rail 355, and the support leg 305 may move (e.g., slide) relative to the server 210. However, at this time, rotational movement between the server 210, the first rail 355, and the support leg 305 may still be prevented. For example, a tab 575 arranged within a cutout 565 located at the first end 345 of the first rail 355 may prevent rotation of the server 210 relative to the first rail 355. Correspondingly, a tab 580 arranged within a cutout 370 located at the second end 335 of the support leg 305 may prevent rotation of the support leg 305 relative to the server 210.

However, as mentioned previously, once an operator has actuated the release mechanisms 315, 325 into the unlocked position the operator may slide the server 210 relative to the first rail 355, which may separate the tab 575 from the cutout 565 and correspondingly permit rotation of the server 210 relative to the first rail 355 about the pivot point 320. Correspondingly, the operator may slide the support leg 305 relative to the server 210, which may separate the tab 580 from the cutout 570 and correspondingly permit rotation of the support leg 305 relative to the server 210 about the pivot point 310.

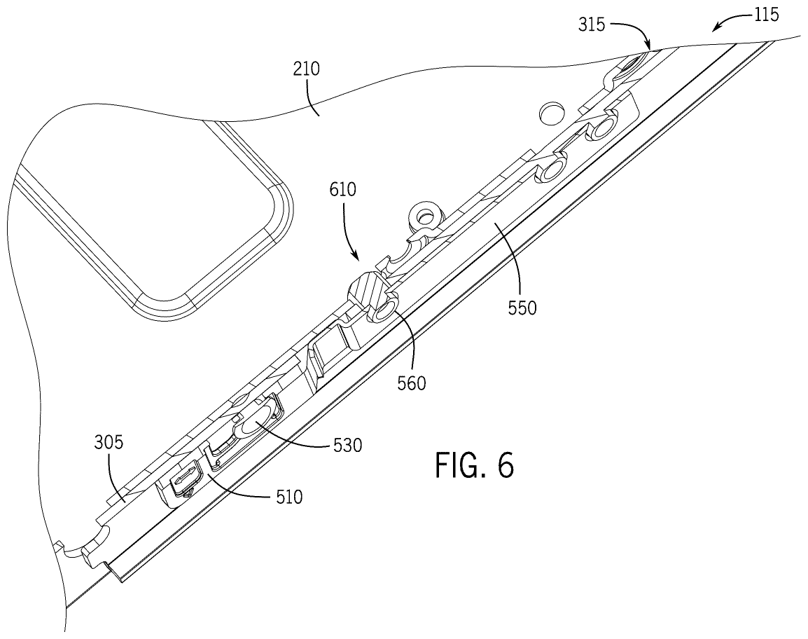

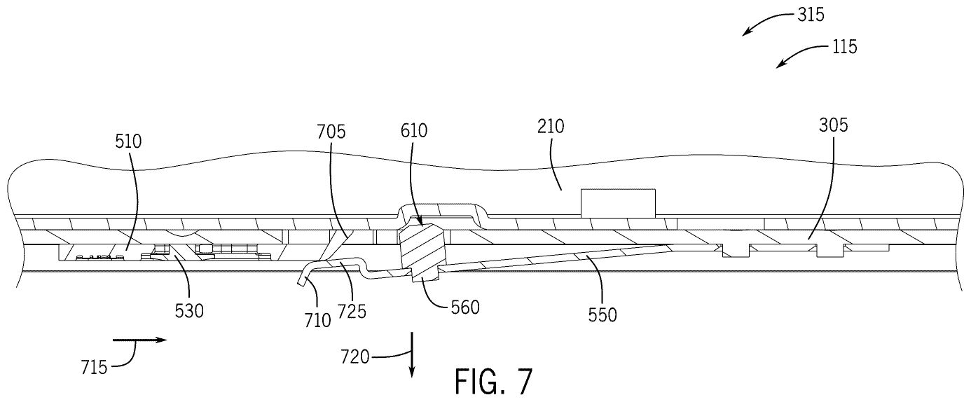

FIGS. 6 and 7 show cross-sectional views of the release mechanism 315 of the support leg 305. However, as mentioned previously, the release mechanism 315 and the release mechanism 325 include similar structure and function similarly. Thus, the below discussion of the release mechanism 315 corresponds to the release mechanism 325.

In one example, as mentioned previously, when the release mechanism 315 is in the locked position, the stopper 560 extends into an opening 610 in the server 210 to prevent movement (e.g., slidable movement) of the support leg 305 with respect to the server 210. However, as the release mechanism 315 is moved into the unlocked position (e.g., in the direction shown by arrow 715) an angled surface 705 of the release mechanism 315 abuts an angled surface 710 of the retention spring 550. Due to the cantilever arrangement of the retention spring 550, the angled surface 705 of the actuator 510 drives a first end 725 of the retention spring 550 outward, away from the server 210 (e.g., in the direction shown by arrow 720). Thus, as the stopper 560 is integrated into the retention spring 550, outward movement of the retention spring 550 separates the stopper 560 from the opening 610, which permits slidable movement of the support leg 305 with respect to the server 210.

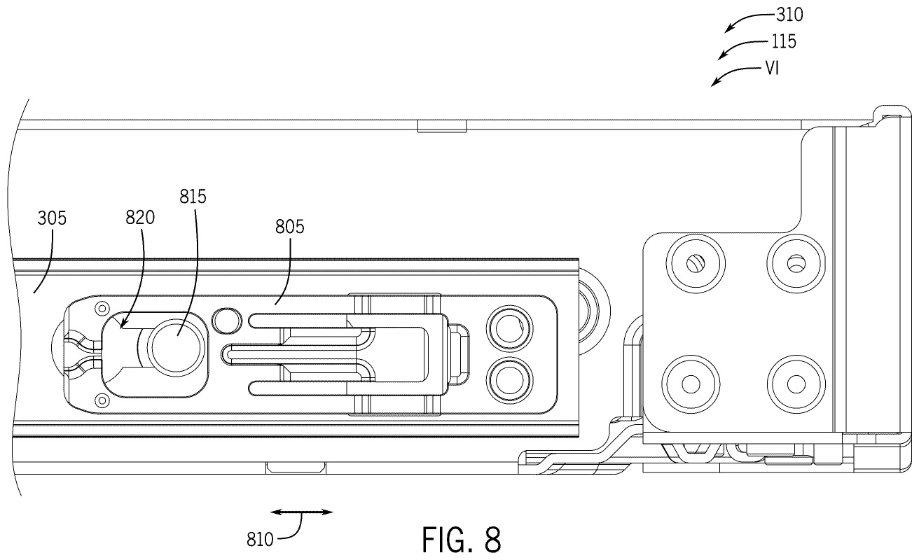

As mentioned previously, in order to facilitate pivotal movement between the support leg 305 and the server 210, the support leg 305 and the server 210 are connected via a pivot point 310. As shown in FIG. 8, the pivot point 310 is formed via a post 815 arranged through a keyhole slot 820 defined by the support leg 305. In one example, the slot 820 may be sized to permit lateral movement of the post 815 (and thus the support leg 305) within the slot 820. However, in one example, to prevent the post 815 from inadvertently coming out of the slot 820, a limiter 805 may be arranged around the post 815 and prevent the post 815 from sliding into a portion of the slot 820. Put differently, the limiter 805 may cut off access to a portion of the slot 820 to prevent the post 815 from being inadvertently removed from the slot 820. Thus, as mentioned previously, the support leg 305 may have a predetermined amount of lateral movement (e.g., shown by arrow 810) with respect to the server 210.

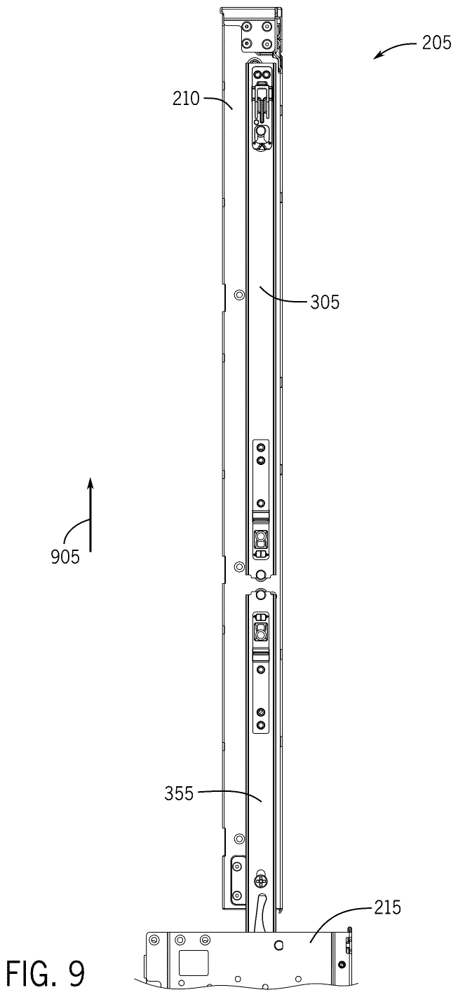

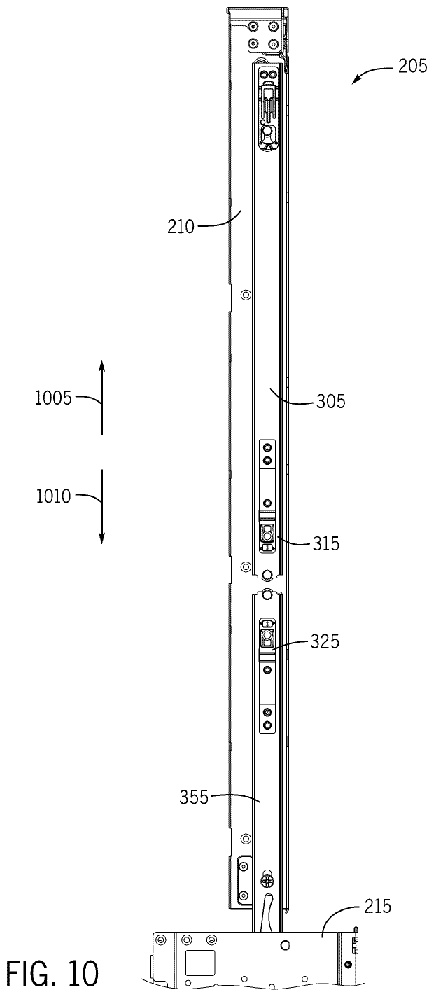

FIGS. 9-12 show the server 210 in various stages of a maintenance position transition process. For example, as shown in FIG. 9, an operator may first remove the server 210 from within the tank 105 and position the server into the expanded position 205. For example, an operator may grasp the server 210 and apply a force to the server 210 in the direction shown by arrow 905, which slides the server vertically out of the tank 105 via the server slides 110. Following this, as shown in FIG. 10, the operator may actuate the release mechanism 315 of the support leg 305 into the unlocked position (e.g., in the direction shown by arrow 1005) and actuate the release button 325 of the first rail 355 into the unlocked position (e.g., in the direction shown by arrow 1010). At this stage, movement (e.g., slidable movement) of server 210 with respect to the first rail 355 is permitted and movement (e.g., slidable movement) of the support leg 305 with respect to the server 210 is permitted.

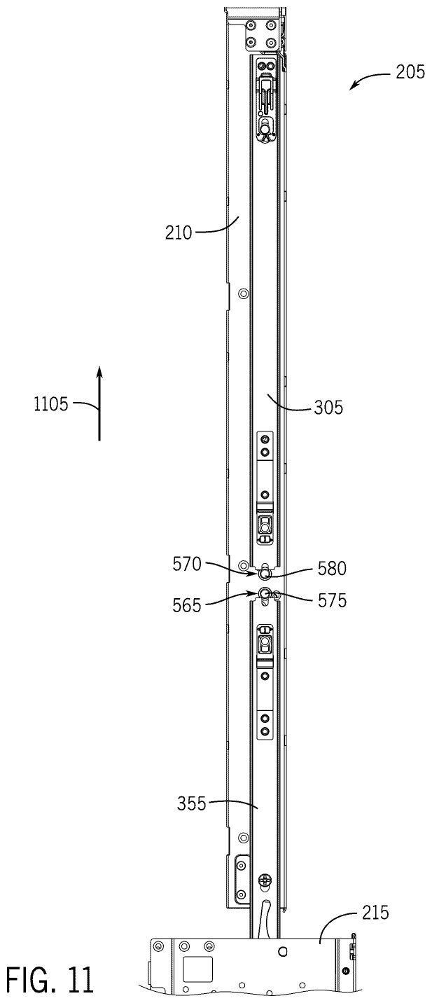

In the next stage, as shown in FIG. 11, the operator may apply a force to lift the server 210 in the direction shown by arrow 1105, which moves the server in the direction shown by arrow 1105, but does not move (e.g., further extend) the first rail 355. As a result, the tab 575 is removed from within the cutout 565, which unlocks rotational movement of the server 210 with respect to the first rail 355. Correspondingly, the operator may apply a force in the direction shown by arrow 1105 to the support leg 305, which moves the support leg 305 in the direction shown by arrow 1105, but does not move the server 210. As a result, the tab 580 is removed from within the cutout 570, which unlocks rotational movement of the support leg 305 with respect to the server 210.

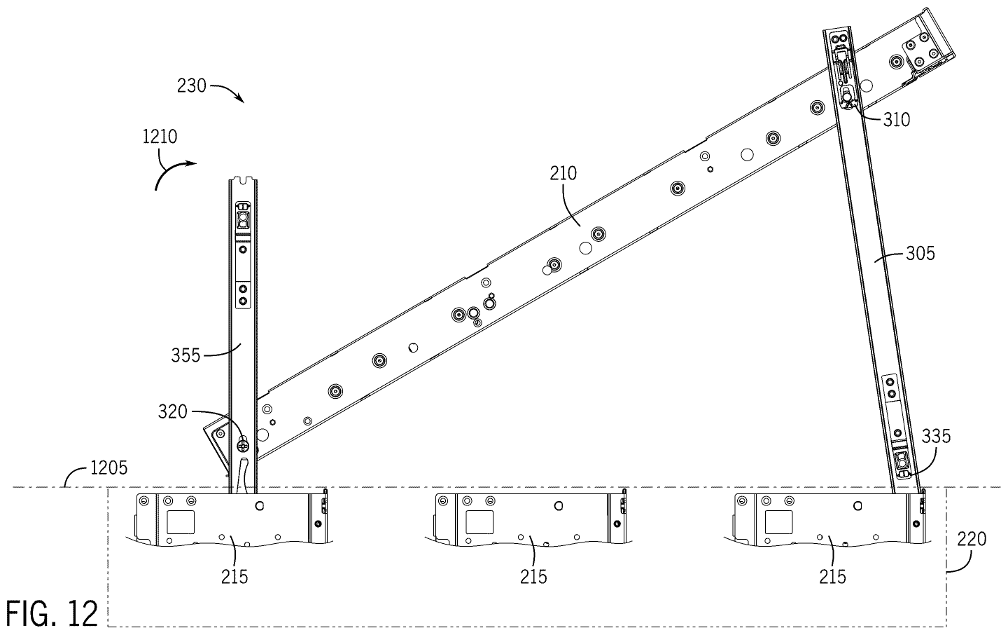

Following this, as shown in FIG. 12, the operator may rotate the server 210 about the pivot point 320 (e.g., in the direction shown by arrow 1210) into a desired maintenance position (e.g., at a desired angle) and extend (e.g., via pivot) the support legs 305 until the support legs 305 contact the upper surface 235 of the walls 220 of the tank 105. In one particular example, the server 210 may be rotated so that the server is angled between 5 and 60 degrees with respect to a horizontal plane 1205 extending parallel to the upper surface 235 of the walls 220 of the tank 105.

In one example, the support legs 305 may be rotated from a first position, parallel to the server 210, into a second position, angle with respect to the server 210 about the pivot point 310. In one example, depending on the degree of rotation of the support legs 305, the angle of the server 210 with respect to the plane 1205 may be different. In another example, rather than having the second end 335 of the support legs 305 contacting the walls 220 of the tank 105, the second end 335 of the support legs 305 may contact an upper surface of the brackets 215.

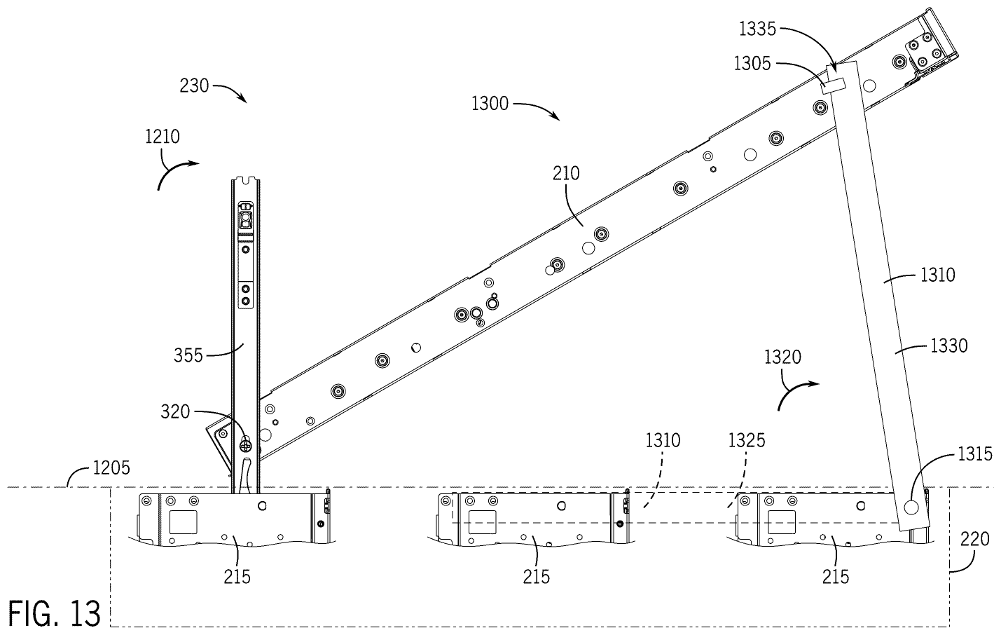

FIG. 13 illustrates another example of a support system 1300 that can be used with the immersion cooling system 100 of FIG. 1 (e.g., as an alternative configuration of the support system 115). As will be recognized, the support system 1300 shares a number of components in common with and operates in a similar fashion to the examples illustrated and described previously. For the sake of brevity, these common features will not be again described below in detail. Rather, previous discussion of commonly named or numbered features, unless otherwise indicated, also applies to example configurations of the support system 1300.

In one example, the support system 1300 includes one or more support legs 1310 pivotally secured to the walls 220 of the tank 105 via a pivot point 1315. Thus, unlike the support legs 305 described previously, the support legs 1310 may be secured directly to the tank 105. In one example, the support legs 1310 may be arranged in a first position 1325 (e.g., aligned parallel with the plane 1205) when not in use. However, when in use, the supports legs 1310 may be arranged in a second position 1330 (e.g., rotated away from the plane 1205 in the direction shown by arrow 1320) to hold the server 210 at a predetermined angle with respect to the plane 1205 (e.g., at about 0 to 60 degrees, inclusive, with respect to the plane 1205).

In one example, in order to secure the support leg 1310 to the server 210, the server may include a post 1305 extending away from opposing sides of the server 210. Correspondingly, the support leg 1310 may include a notch 1335 configured to receive the post 1305. Thus, in use, the server 210 may be rotated with respect to the first rail 355 as discussed previously. Following this, the support leg 1310 may be moved from the first position 1325 to the second position 1330, with the post 1305 of the server 210 arranged within the notch 1335 of the support leg 1310. Thus, the server 210 may be held in the maintenance position 230, without having the support legs 1310 fixed to the server 210.

In some implementations, devices or systems disclosed herein can be utilized, manufactured, or installed using methods embodying aspects of the invention. Correspondingly, any description herein of particular features, capabilities, or intended purposes of a device or system is generally intended to include disclosure of a method of using such devices for the intended purposes, a method of otherwise implementing such capabilities, a method of manufacturing relevant components of such a device or system (or the device or system as a whole), and a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of. ” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C”indicate options of: A and B; B and C; A and C; and A, B, and C.

As used herein, unless otherwise defined or limited, directional terms are used for convenience of reference for discussion of particular figures or examples. For example, references to downward (or other) directions or top (or other) positions may be used to discuss aspects of a particular example or figure, but do not necessarily require similar orientation or geometry in all installations or configurations.

Also as used herein, unless otherwise limited or defined, “substantially parallel” indicates a direction that is within ±12 degrees of a reference direction (e.g., within ±6 degrees), inclusive. For a path that is not linear, the path can be considered to be substantially parallel to a reference direction if a straight line between end-points of the path is substantially parallel to the reference direction or a mean derivative of the path within a common reference frame as the reference direction is substantially parallel to the reference direction.

Also as used herein, unless otherwise limited or defined, “substantially perpendicular” indicates a direction that is within ±12 degrees of perpendicular a reference direction (e.g., within ±6 degrees), inclusive. For a path that is not linear, the path can be considered to be substantially perpendicular to a reference direction if a straight line between end-points of the path is substantially perpendicular to the reference direction or a mean derivative of the path within a common reference frame as the reference direction is substantially perpendicular to the reference direction.

Also as used herein, unless otherwise limited or defined, “integral” and derivatives thereof (e.g., “integrally”) describe elements that are manufactured as a single piece without fasteners, adhesive, or the like to secure separate components together. For example, an element stamped, cast, or otherwise molded as a single-piece component from a single piece of sheet metal or using a single mold, without rivets, screws, or adhesive to hold separately formed pieces together is an integral (and integrally formed) element. In contrast, an element formed from multiple pieces that are separately formed initially then later connected together, is not an integral (or integrally formed) element.

Additionally, unless otherwise specified or limited, the terms “about” and “approximately,” as used herein with respect to a reference value, refer to variations from the reference value of ±15% or less, inclusive of the endpoints of the range. Similarly, the term “substantially equal” (and the like) as used herein with respect to a reference value refers to variations from the reference value of less than ±10%, inclusive. Where specified, “substantially” can indicate in particular a variation in one numerical direction relative to a reference value. For example, “substantially less” than a reference value (and the like) indicates a value that is reduced from the reference value by 10% or more, and “substantially more” than a reference value (and the like) indicates a value that is increased from the reference value by 10% or more.

Also as used herein, unless otherwise limited or specified, “substantially identical” refers to two or more components or systems that are manufactured or used according to the same process and specification, with variation between the components or systems that are within the limitations of acceptable tolerances for the relevant process and specification. For example, two components can be considered to be substantially identical if the components are manufactured according to the same standardized manufacturing steps, with the same materials, and within the same acceptable dimensional tolerances (e.g., as specified for a particular process or product).

Unless otherwise specifically indicated, ordinal numbers are used herein for convenience of reference, based generally on the order in which particular components are presented in the relevant part of the disclosure. In this regard, for example, designations such as “first,” “second,” etc., generally indicate only the order in which a thus-labeled component is introduced for discussion and generally do not indicate or require a particular spatial, functional, temporal, or structural primacy or order.

The previous description of the disclosed embodiments is provided to enable any person skilled in the art to make or use the invention. Given the benefit of this disclosure, various modifications to these embodiments will be readily apparent to those skilled in the art, and the principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A server system for use with a tank that contains cooling fluid, the server system comprising:
a server slide that is immersible within the cooling fluid to movably support a server chassis relative to the tank and the cooling fluid, the server slide being extendable along a vertical direction between a contracted orientation, in which the server slide supports the server chassis with the server chassis submerged within the cooling fluid, and an extended orientation, in which the server slide supports the server chassis with the server chassis at least partly outside the cooling fluid; and
a support leg secured to the server chassis in a first position, the support leg being moveable from the first position to a second position in which the support leg supports the server chassis at an angle relative to a horizontal plane.

2. The server system of claim 1, wherein the support leg is rotatable with respect to the server chassis about a first pivot point to move from the first position to the second position.

3. The server system of claim 2, wherein, in the first position, the support leg extends along the server chassis to form part of the server slide that guides the extension of the server slide along the vertical direction.

4. The server system of claim 2, wherein the support leg is slidable along the chassis to be released for rotation to the second position.

5. The server system of claim 4, wherein the support leg includes a first release mechanism to selectively lock and unlock slidable movement of the support leg, the first release mechanism including an actuator that is movable to engage a retention spring to unlock slidable movement of the support leg with respect to the server chassis.

6. The server system of claim 5, wherein, the actuator includes an angled surface that contacts the retention spring to cause the retention spring to disengage a stopper from the server chassis to unlock slidable movement of the support leg with respect to the server chassis.

7. The server system of claim 2, wherein the server slide further includes a first rail that supports the server relative to the tank and guides the extension of the server in the vertical direction; and
wherein the server chassis is rotatable with respect to the first rail about a second pivot point to further support the server chassis at the angle relative to a horizontal plane.

8. The server system of claim 7, wherein the server chassis is slidable relative to the first rail to be released for rotation selectively lock and unlock slidable movement of the server chassis with respect to the first rail.

9. The server system of claim 1, wherein the support leg supports the server chassis at an angle of 0 to 60 degrees, inclusive, relative to the horizontal plane.

10. A method of supporting a server system for use with a tank that contains cooling fluid, the method comprising:
moving a server chassis upward along a vertical direction to raise the server chassis out of the tank of cooling fluid;
pivoting a first support leg, relative to the server chassis, to extend at a first-leg non-zero angle relative to an elongate direction of the server chassis; and
supporting the server chassis with the first support leg, to drain the cooling fluid from the server chassis, with the server chassis at a chassis non-zero angle relative to a horizontal plane.

11. The method of claim 10, further comprising:
pivoting the server chassis, relative to a second support leg, so that the elongate direction of the server chassis extends at a second-leg non-zero angle relative to the second support leg; and
further supporting the server chassis with the second support leg to hold the server chassis at the chassis non-zero angle.

12. The method of claim 11, further comprising:
unlocking movement of the first support leg with respect to the server chassis via actuation of a first release button of the support leg; and
unlocking movement of the server chassis with respect to the second support leg via actuation of a second release button.

13. The method of claim 11, wherein one or more of the first support leg or the second support leg forms a rail of a server slide and guides movement of the server chassis along the vertical direction.

14. The method of claim 13, wherein the first support leg and the second support leg collectively form the rail of the server slide and guide movement of the server chassis along the vertical direction.

15. The method of claim 14, further comprising:
sliding the first support leg along the server chassis to release the first support leg to be pivoted relative to the server chassis; and
sliding the server chassis along the second support leg to release the server chassis to be pivoted relative to the second support leg.

16. The method of claim 10, wherein the first support leg supports the server chassis at an angle of 5 to 60 degrees inclusive, relative to the horizontal plane.

17. A server system comprising:
a tank that contains cooling fluid
a server chassis;
a server slide secured to the server chassis to slidably move the server chassis along a vertical direction between a contracted orientation, in which the server slide supports the server chassis with the server chassis submerged within the cooling fluid, and an extended orientation, in which the server slide supports the server chassis with the server chassis at least partly outside the cooling fluid; and
a first support leg that is pivotable relative to the server chassis to extend at a first-leg non-zero angle relative to an elongate direction of the server chassis to support the server chassis at a chassis non-zero angle relative to a horizontal plane, to drain the cooling fluid from the server chassis.

18. The server system of claim 17, wherein the first support leg forms a rail of the server slide that guides the slidable movement of the server chassis along the vertical direction.

19. The server system of claim 17, further comprising:
a second support leg that is pivotably secured to the server chassis to further support the server chassis at the chassis non-zero angle.

20. The server system of claim 19, wherein the first support leg and the second support leg collectively form a rail of the server slide that guides the slidable movement of the server chassis along the vertical direction.
